(19) United States
(12) Patent Application Publication
(10) Pub. No.: US 2018/0159076 A1
(43) Pub. Date: Jun. 7, 2018

(54) ORGANIC LIGHT EMITTING DIODE DISPLAY DEVICE AND MANUFACTURING METHOD THEREOF

(71) Applicant: SAMSUNG DISPLAY CO., LTD., Yongin-si (KR)

(72) Inventors: Haeyoung YUN, Yongin-si (KR); Junghyun CHO, Yongin-si (KR); Junyoung KIM, Yongin-si (KR)

(21) Appl. No.: 15/827,377

(22) Filed: Nov. 30, 2017

(30) Foreign Application Priority Data
Dec. 2, 2016 (KR) 10-2016-0163690

(51) Int. Cl. H01L 51/52; H01L 27/32

(52) U.S. Cl. CPC H01L 51/5253; H01L 27/3246; H01L 2227/323; H01L 27/3248; H01L 27/3276

(57) ABSTRACT

An organic light emitting diode display device includes a first electrode on a protective layer, a pixel defining layer on the protective layer and defining an opening that exposes at least a portion of the first electrode, an organic light emitting layer on the first electrode, and a second electrode on the light emitting layer. The protective layer has a recessed portion overlapping the opening, and the recessed portion is spaced apart from an edge of the opening on a plane.

### CROSS-REFERENCE TO RELATED APPLICATION

Korean Patent Application No. 10-2016-0163690, filed on Dec. 2, 2016, and entitled, “Organic Light Emitting Diode Display Device And Manufacturing Method Thereof,” is incorporated by reference herein in its entirety.

### 1. Field

One or more embodiments described herein relate to an organic light emitting diode display device and a method of manufacturing the same.

### 2. Description of the Related Art

Organic light emitting diode (OLED) display devices have low power consumption, high luminance, and high respond speed. One type of OLED display device has a multilayer structure including an OLED. Such a structure may produce color shift according to viewing angle that degrades display quality.

### SUMMARY

In accordance with one or more embodiments, an organic light emitting diode display device includes a substrate; a protective layer on the substrate; a first electrode on the protective layer; a pixel defining layer on the protective layer and defining an opening that exposes at least a portion of the first electrode; an organic light emitting layer on the first electrode; and a second electrode on the light emitting layer, wherein the protective layer has a recessed portion overlapping the opening and wherein the recessed portion is spaced apart from an edge of the opening on a plane.

A height of the protective layer may be equal to height of a surface of the substrate at a boundary where the protective layer overlaps the pixel defining layer. A difference between a height of the protective layer and a height of a surface of the substrate at a boundary where the protective layer overlaps the pixel defining layer may be about 0.1 μm or less. A height of the edge of the opening may be equal to a height of a surface of the substrate. A difference between a height of the edge of the opening and a height of a surface of the substrate may be about 0.1 μm or less. The recessed portion may be spaced apart from the edge of the opening by about 0.5 μm to about 5.0 μm. The recessed portion may be spaced apart from the edge of an opening by about 0.5 μm to about 2.0 μm on a plane.

At least a portion of an edge of the recessed portion may be parallel to the edge of the opening. The recessed portion may have a width ranging from about 1.0 μm to about 2.0 μm. The recessed portion may have a depth ranging from about 0.2 μm to about 1.0 μm. The recessed portion may have a depth ranging from about 0.3 μm to about 0.7 μm.

The display device may include a thin film transistor between the substrate and the protective layer, wherein the first electrode contacts the thin film transistor through a contact hole in the protective layer and wherein a depth of the recessed portion is less than a depth of the contact hole. The protective layer may include a plurality of recessed portions arranged at a pitch ranging from about 1 μm to about 6 μm. Each of the recessed portions may have a linear planar shape. The recessed portions may be parallel to each other. The recessed portions may be in a radial direction. Each of the recessed portions may have a dot planar shape. The recessed portions may have different depths. The display device may include a spacer on the pixel defining layer.

In accordance with one or more other embodiments, a method for manufacturing an organic light emitting diode display device includes applying a photosensitive material on a substrate to form a photosensitive material layer; patterning the photosensitive material layer to form a protective layer having a recessed portion; forming a first electrode on the protective layer and covering the recessed portion; forming a pixel defining layer on the protective layer, the pixel defining layer defining an opening that exposes at least a portion of the first electrode; forming a light emitting layer at the opening of the first electrode; and forming a second electrode on the light emitting layer, wherein the recessed portion overlaps the opening and is spaced apart from an edge of the opening on a plane.

A height of the protective layer may be equal to a height of a surface of the substrate at a boundary where the protective layer overlaps the pixel defining layer. A difference between a height of the protective layer and a height of a surface of the substrate at a boundary where the protective layer overlaps the pixel defining layer may be about 0.1 μm or less. Forming the protective layer may include patterning the photosensitive material layer and then thermally curing the patterned photosensitive material layer.

### BRIEF DESCRIPTION OF THE DRAWINGS

Features will become apparent to those of skill in the art by describing in detail exemplary embodiments with reference to the attached drawings in which:

FIG. 1 illustrates an embodiment of a pixel;

FIG. 2 illustrates a circuit diagram embodiment of the pixel;

FIG. 3 illustrates a cross-sectional view taken along line I-I′ in FIG. 1;

FIGS. 4A illustrates an embodiment of a first electrode and an opening, and

FIG. 4B illustrates an embodiment of a recessed portion below the first electrode;

FIGS. 5A and 5B illustrate another embodiment including a first electrode, an opening, and a recessed portion;

FIG. 6 illustrates another embodiment including a first electrode, an opening, and a recessed portion;

FIG. 7 illustrates another embodiment including a first electrode, an opening, and a recessed portion;

FIGS. 8A and 8B illustrate another embodiment including a first electrode, an opening, and a recessed portion;

FIG. 9A illustrates an example of white angular dependency (WAD), and FIG. 9B illustrates an example of wavelength variation according to viewing angle;

FIG. 10 illustrates an example of resonance at a recessed portion;

FIG. 11 illustrates an embodiment of an OLED display device;

FIG. 12 illustrates another embodiment of an OLED display device;

FIGS. 13A-13J illustrate stages corresponding to an embodiment of a method for manufacturing an OLED display device;

FIGS. 14A and 14B illustrate stages of another embodiment of a method for manufacturing an OLED display device;

FIG. 15 illustrates another embodiment of a pixel;

FIG. 16 illustrates a cross-sectional view taken along line IT-II′ in FIG. 15;

FIG. 17 illustrates another embodiment of a pixel;

FIG. 18 illustrates a cross-sectional view taken along line III-III′ FIG. 17; and

FIG. 19 illustrates another embodiment of a pixel.

### DETAILED DESCRIPTION

Example embodiments are described with reference to the drawings; however, they may be embodied in different forms and should not be construed as limited to the embodiments set forth herein. Rather, these embodiments are provided so that this disclosure will be thorough and complete, and will convey exemplary implementations to those skilled in the art. The embodiments (or portions thereof) may be combined to form additional embodiments

In the drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

When an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless there is different disclosure.

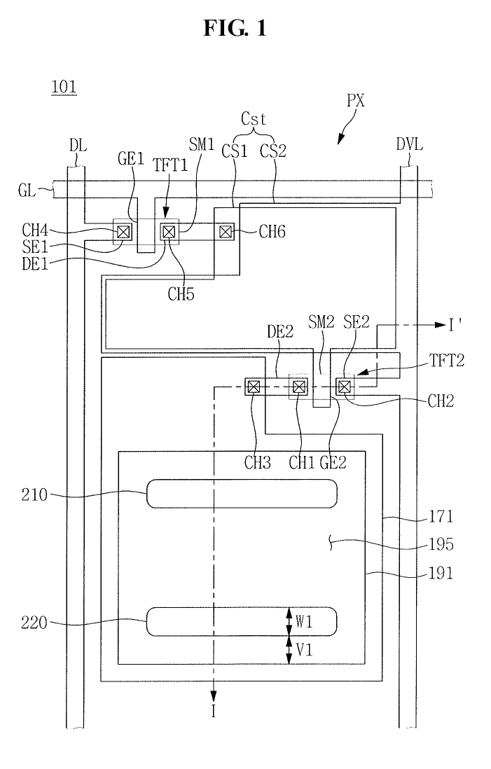

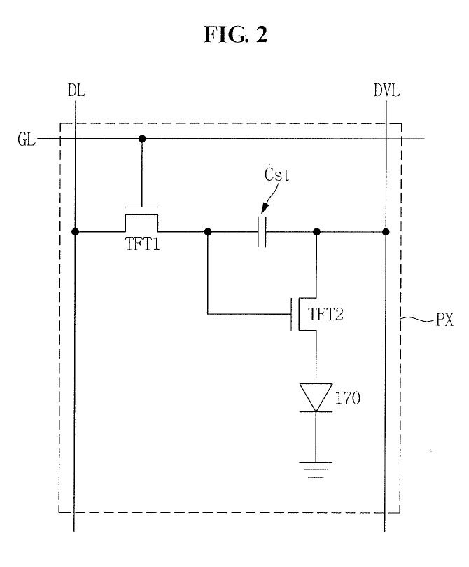

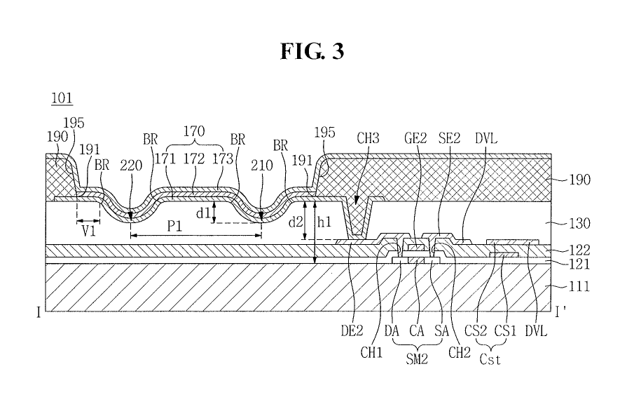

FIG. 1 illustrates an embodiment of a pixel PX of an organic light emitting diode display device 101. FIG. 2 illustrates a circuit diagram embodiment of the pixel PX. FIG. 3 illustrates a cross-sectional view taken along line I-I′ in FIG. 1. The OLED display device 101 includes a plurality of pixels represented by pixel PX. The pixel PX may be considered to be the smallest unit emitting light for displaying an image. In one embodiment, the pixel PX may be a sub-pixel.

Referring to FIGS. 1, 2 and 3, the pixel PX includes a switching thin film transistor TFT1, a driving thin film transistor TFT2, an OLED 170, and a capacitor Cst. The pixel PX may generate light of a predetermined color, e.g., red, green, blue, cyan, magenta, yellow, white, or another color.

The pixel PX is connected to a gate line GL, a data line DL, and a driving voltage line DVL. The gate line GL extends in one direction, and the data line DL extends in another direction intersecting the gate line GL. Referring to FIG. 1, the driving voltage line DVL extends in substantially a same direction as the data line DL. The gate line GL transmits a scan signal, the data line DL transmits a data signal, and the driving voltage line DVL provides a driving voltage.

The driving thin film transistor TFT2 controls the OLED 170, and the switching thin film transistor TFT1 controls switching of the driving thin film transistor TFT2. The pixel PX may have a different structure in another embodiment, e.g., one or more thin film transistors and/or one or more capacitors.

The switching thin film transistor TFT1 includes a first gate electrode GE1, a first source electrode SE1, a first drain electrode DE1, and a first semiconductor layer SM1. The first gate electrode GE1 is connected to the gate line GL and the first source electrode SE1 is connected to the data line DL.

The first drain electrode DE1 is connected to a first capacitor plate CS1 through a fifth contact hole CH5 and a sixth contact hole CH6. The switching thin film transistor TFT1 transmits a data signal applied to the data line DL to the driving thin film transistor TFT2 according to a scan signal applied to the gate line GL.

The driving thin film transistor TFT2 includes a second gate electrode GE2, a second source electrode SE2, a second drain electrode DE2, and a second semiconductor layer SM2. The second gate electrode GE2 is connected to a first capacitor plate CS1. The second source electrode SE2 is connected to the driving voltage line DVL. The second drain electrode DE2 is connected to a first electrode 171 through a third contact hole CH3.

The first electrode 171 is connected to the second drain electrode DE2 of the driving TFT2. An organic light emitting layer 172 is on the first electrode 171, and a second electrode 173 is on the organic light emitting layer 172. A common voltage is applied to the second electrode 173. The organic light emitting layer 172 generates light according to an output signal of the driving thin film transistor TFT2.

The capacitor Cst is connected between the second gate electrode GE2 and the second source electrode SE2 of the driving thin film transistor TFT2. The capacitor Cst charges and maintains a signal input to the second gate electrode GE2 of the driving thin film transistor TFT2. The capacitor Cst includes the first capacitor plate CS1 connected to the first drain electrode DE1 through the sixth contact hole CH6, and a second capacitor plate CS2 connected to the driving voltage line DVL.

Referring to FIGS. 1, 2 and 3, thin film transistors TFT1 and TFT2 and the OLED 170 are on a substrate 111. The substrate 111 may include, for example, an insulating material such as glass, plastic, quartz, or the like. The material for the substrate 111 may be selected from materials exhibiting a predetermined level of mechanical strength, thermal stability, transparency, surface smoothness, ease of handling, and/or water resistance.

A buffer layer may be on the substrate 111 to substantially prevent diffusion of impurities into switching thin film transistor TFT1 and driving thin film transistor TFT2.

The first semiconductor layer SM1 and the second semiconductor layer SM2 are on the substrate 111. The first semiconductor layer SM1 and the second semiconductor layer SM2 include a semiconductor material and act as active layers of the switching thin film transistor TFT1 and the driving thin film transistor TFT2, respectively. Each of the first semiconductor layer SM1 and the second semiconductor layer SM2 includes a channel area CA between a source area SA and a drain area DA.

The first semiconductor layer SM1 and the second semiconductor layer SM2 may include amorphous silicon, polycrystalline silicon, or the like, or may include an oxide semiconductor. For example, each of the first semiconductor layer SM1 and the second semiconductor layer SM2 may include an inorganic semiconductor material or an organic semiconductor material. The source area SA and the drain area DA may be doped with an n-type impurity or a p-type impurity.

A gate insulating layer 121 is on the first semiconductor layer SM1 and the second semiconductor layer SM2. The gate insulating layer 121 protects the first semiconductor layer SM1 and the second semiconductor layer SM2. The gate insulating layer 121 may include an organic insulating material or an inorganic insulating material.

The first gate electrode GE1 and the second gate electrode GE2 are on the gate insulating layer 121. The first gate electrode GE1 and the second gate electrode GE2 overlap the channel areas CA of the first semiconductor layer SM1 and the second semiconductor layer SM2, respectively. The first capacitor plate CS1 is on the gate insulating layer 121. The second gate electrode GE2 may be formed integrally with the first capacitor plate CS1.

An insulating interlayer 122 is on the first gate electrode GEL the second gate electrode GE2, and the first capacitor plate CS1. The insulating interlayer 122 may include an organic insulating material or an inorganic insulating material.

The first source electrode SE1, the first drain electrode DE1, the second source electrode SE2, and the second drain electrode DE2 are on the insulating interlayer 122. The second drain electrode DE2 contacts the drain area DA of the second semiconductor layer SM2 through a first contact hole CHI in the gate insulating layer 121 and the insulating interlayer 122. The second source electrode SE2 contacts the source area SA of the second semiconductor layer SM2 through a second contact hole CH2 in the gate insulating layer 121 and the insulating interlayer 122. The first source electrode SE1 contacts the first semiconductor layer SM1 through a fourth contact hole CH4 in the gate insulating layer 121 and the insulating interlayer 122. The first drain electrode DE1 contacts the first semiconductor layer SM1 through the fifth contact hole CH5 in the gate insulating layer 121 and the insulating interlayer 122.

The data line DL, the driving voltage line DVL, and the second capacitor plate CS2 are on the insulating interlayer 122. The second capacitor plate CS2 may be integrally formed with the driving voltage line DVL.

A protective layer 130 is on the first source electrode SE1, the first drain electrode DE1, the second source electrode SE2, and the second drain electrode DE2. The protective layer 130 protects the switching thin film transistor TFT1 and the driving thin film transistor TFT2 and also serves to planarize an upper surface thereof. Referring to FIGS. 1 and 3, the protective layer 130 has recessed portions 210 and 220.

The first electrode 171 is on the protective layer 130 and may be, for example, an anode. According to an exemplary embodiment, the first electrode 171 is a pixel electrode. The first electrode 171 is connected to the second drain electrode DE2 of the driving thin film transistor TFT2 through the third contact hole CH3 in the protective layer 130.

A pixel defining layer 190 partitions a light emission area and is on the protective layer 130. The pixel defining layer 190 may include, for example, a polymer organic material. The pixel defining layer 190 may include at least one of, for example, a polyimide (PI) resin, a polyacrylic resin, a PET resin and a PEN resin. According to an exemplary embodiment, the pixel defining layer 190 includes a PI resin.

The pixel defining layer 190 defines an opening 195 and the first electrode 171 is exposed from the pixel defining layer 190 through the opening 195. A light emission area of the OLED 170 is defined by the opening 195, and the light emission area is also referred to as a pixel area.

Referring to FIGS. 1 and 3, the pixel defining layer 190 exposes an upper surface of the first electrode 171 and protrudes from the first electrode 171 along the periphery of each of the pixels PX. The first electrode 171 overlaps at least a portion of the pixel defining layer 190 and does not overlap the pixel defining layer 190 at the opening 195. The opening 195 may be defined as an area of an upper portion of the first electrode 171 that does not overlap the pixel defining layer 190. In one embodiment, a boundary between the pixel defining layer 190 and the first electrode 171 at the opening 195 may be referred to as an edge 191 of the opening 195.

The first electrode 171 has conductivity and may be a transmissive electrode, a transflective electrode, or a reflective electrode. When the first electrode 171 is a transmissive electrode, the first electrode 171 includes a transparent conductive oxide. The transparent conductive oxide may include, for example, at least one of indium tin oxide (ITO), indium zinc oxide (IZO), zinc oxide (ZnO), and indium tin zinc oxide (ITZO). When the first electrode 171 is a transflective electrode or a reflective electrode, the first electrode 171 may include, for example, at least one of Ag, Mg, Al, Pt, Pd, Au, Ni, Nd, Ir, Cr, and Cu.

The organic light emitting layer 172 is on the first electrode 171. For example, the organic light emitting layer 172 is on the first electrode 171 at the opening 195. The organic light emitting layer 172 may be on a sidewall of the opening 195 defined by the pixel defining layer 190 and on the pixel defining layer 190.

The organic light emitting layer 172 includes a light emitting material. In one embodiment, the organic light emitting layer 172 may include a host and a light emitting dopant. The organic light emitting layer 172 may be formed, for example, by a vacuum deposition method, a spin coating method, a cast method, a Langmuir-Blodgett (LB) method, an inkjet printing method, a laser printing method, a laser induced thermal imaging (LITI) method, or another method.

At least one of a hole injection layer (HIL) and a hole transport layer (HTL) may be between the first electrode 171 and the organic light emitting layer 172.

The second electrode 173 is on the organic light emitting layer 172 and may be, for example, a common electrode and may be a cathode. The second electrode 173 may be a transmissive electrode, a transflective electrode, or a reflective electrode. When the second electrode 173 is a transmissive electrode, the second electrode 173 may include. for example, at least one of Li, Ca, LiF/Ca, LiF/Al, Al, Mg, BaF, Ba, Ag and Cu. For example, the second electrode 173 may include a mixture of Ag and Mg.

When the second electrode 173 is a transflective electrode or a reflective electrode, the second electrode 173 may include, for example, at least one of Ag, Mg, Al, Pt, Pd, Au, Ni, Nd, Ir, Cr, Li, Ca, LiF/Ca, LiF/Al, Mo, Ti and Cu. In one embodiment, the second electrode 173 may include a transparent conductive layer including indium tin oxide (ITO), indium zinc oxide (IZO), zinc oxide (ZnO), indium-zinc-tin oxide (IZTO), and the like, in addition to the transflective electrode or the reflective electrode.

At least one of an electron transport layer (ETL) and an electron injection layer (EIL) may be between the organic light emitting layer 172 and the second electrode 173.

When the OLED 170 is a top emission-type, the first electrode 171 may be a reflective electrode and the second electrode 173 may be a transmissive electrode or a transflective electrode. When the OLED 170 is a bottom emission-type, the first electrode 171 may be a transmissive electrode or a transflective electrode, and the second electrode 173 may be a reflective electrode.

According to an exemplary embodiment, the OLED 170 is a top emission-type, the first electrode 171 is a reflective electrode and the second electrode 173 is a transflective electrode.

According to an exemplary embodiment, the protective layer 130 has recessed portions 210 and 220 which overlap the opening 195. The recessed portions 210 and 220 are, on a plane. spaced apart from the edge 191 of the opening 195. For example, a boundary BR of the recessed portions 210 and 220 is spaced apart from the edge 191 of the opening 195 on a plane.

The edge 191 of the opening 195 is a boundary of an area of the opening 195 and may be defined, for example, as a boundary at which the pixel defining layer 190 contacts the first electrode 171. The edge 191 of the opening 195 may be defined as a boundary at which the protective layer 130 overlaps the pixel defining layer 190 on a plane.

Referring to FIGS. 1 and 3, the recessed portions 210 and 220 are not below the edge 191 of the opening 195. The recessed portions 210 and 220 may not overlap the edge 191 of the opening 195.

Accordingly, the protective layer 130 has a substantially equal height hl, with respect to a surface of the substrate 111, at a boundary where the protective layer 130 overlaps the pixel defining layer 190. For example, the protective layer 130 has a substantially equal height hl along the edge 191 of the opening 195. In one embodiment, the protective layer 130 may have a height difference of about 0.1 μm or less with respect to the surface of the substrate 111 at the boundary where the protective layer 130 overlaps the pixel defining layer 190.

According to an exemplary embodiment, the edges 191 of the opening 195 has a substantially equal height with respect to the surface of the substrate 111. For example, the edge 191 of the opening 195 may have a height difference of about 0.1 μm or less with respect to the surface of the substrate 111.

The pixel defining layer 190 may be formed by a patterning process such as a photolithography method. In such an exemplary embodiment, the edge 191 of the opening 195 corresponds to a boundary of the pattern. However, in the case where a lower surface of the pattern boundary is not flat and not uniform, it may be difficult to form uniform pattern. According to an exemplary embodiment, since the edge 191 of the opening 195 is flat, pattern defects may be substantially prevented in the process of forming the pixel defining layer.

As such, in order to allow the edge 191 of the opening 195 to be flat, the recessed portions 210 and 220 are spaced apart from the edge 191 of the opening 195. According to an exemplary embodiment, the recessed portions 210 and 220 may be spaced apart from the edge 191 of the opening 195, on a plane, by a distance of about 0.5 μm to about 5.0 μm. In such an exemplary embodiment a distance V1 between the recessed portions 210 and 220 and the edge 191 of the opening 195 is defined as a distance between the edge 191 of the opening 195 and the boundary BR of the recessed portions 210 and 220.

The distance V1 between the recessed portions 210 and 220 and the edge 191 of the opening 195 may vary depending on the size of the OLED 170. For example, the recessed portions 210 and 220 may be spaced apart from the edge 191 of opening 195 by a distance of about 0.5 μm to about 2.0 μm on a plane, or more than about 5.0 μm.

At least a portion of the boundary BR of the recessed portions 210 and 220 is parallel to the edge 191 of the opening 195. Referring to FIG. 1, at least one side of the boundary BR of the recessed portions 210 and 220 is parallel to the edge 191 of the opening 195.

When the edge BR of the recessed portions 210 and 220 is parallel to the edge 191 of the opening 195, the distance V1 between the recessed portions 210 and 220 and the edge 191 of the opening 195 may be easily maintained. Accordingly, the pattern may be uniformly formed in the process of forming the pixel defining layer 190.

According to an exemplary embodiment, the recessed portions 210 and 220 may have a width W1 ranging from about 1.0 μm to about 2.0 μm. In addition, the recessed portions 210 and 220 may have a depth d1 ranging from about 0.2 μm to about 1.0 μm. For example, the recessed portions 210 and 220 may have a depth d1 ranging from about 0.3 μm to about 0.7 μm.

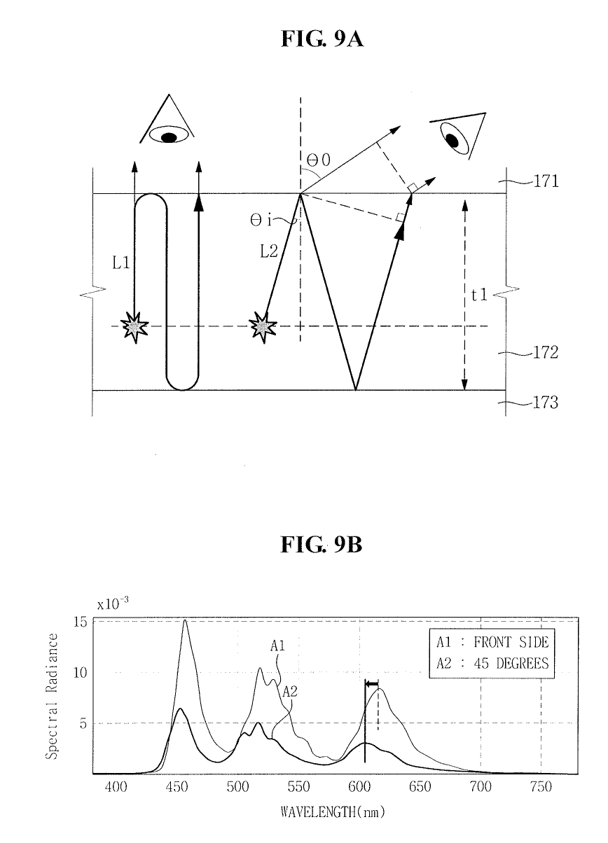

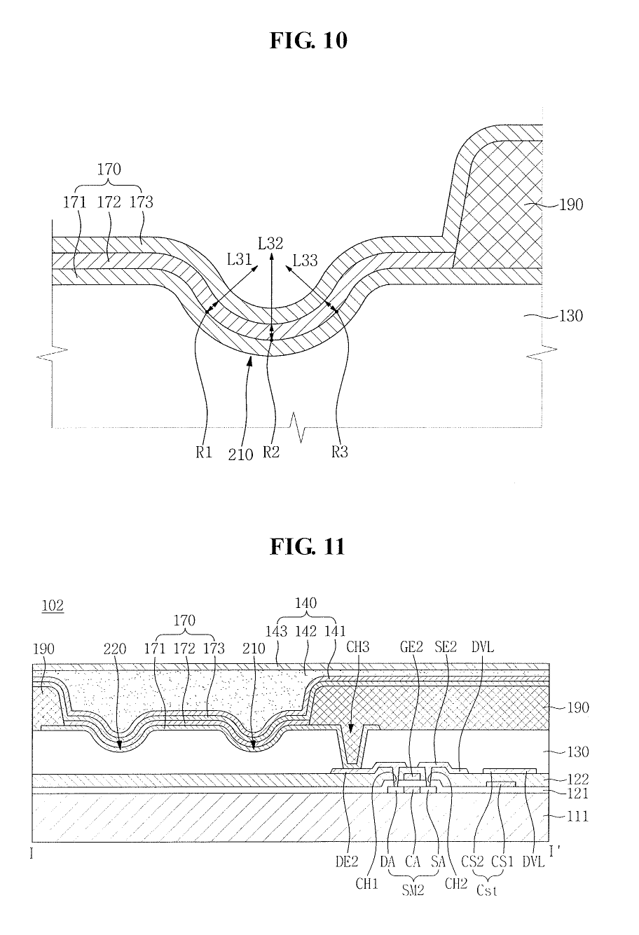

When the recessed portions 210 and 220 have such width W1 and depth d1, the light generated in the organic light emitting layer 172 may resonate in the lateral direction (e.g., see FIG. 10). Accordingly, the occurrence of color shift and white angular dependency (WAD) according to the viewing angle may be suppressed (e.g., see FIGS. 9A and 9B).

Referring to FIGS. 1 and 3, a plurality of line-shaped recessed portions 210 and 220 overlapping one first electrode 171 may be defined in the protective layer 130. For example, a plurality of recessed portions 210 and 220 may correspond to one opening 195. Referring to FIG. 1, the plurality of line-shaped recessed portions 210 and 220 are parallel to each other.

The recessed portions 210 and 220 may be defined at a pitch P1 ranging from about 1 μm to about 6 μm. The pitch among the recessed portions 210 and 220 may vary depending on the area of the first electrode 171 and the size of the OLED 170.

In addition, referring to FIGS. 1 and 3, the first electrode 171 contacts the driving thin film transistor TFT2 through the third contact hole CH3 in the protective layer 130. In such an exemplary embodiment, the recessed portions 210 and 220 have a depth d1 which is less than a depth d2 of the third contact hole CH3 (d2>d1).

Referring to FIG. 3, the first electrode 171 is on the recessed portions 210 and 220. For example, the first electrode 171 overlaps the recessed portions 210 and 220. Accordingly, the first electrode 171 also has a recessed portion.

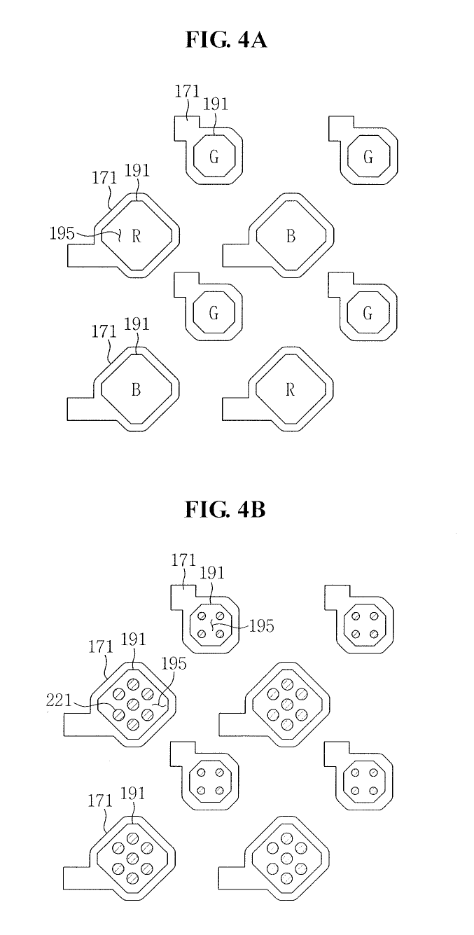

FIG. 4A illustrates a plan view of another embodiment of a first electrode 171 and an opening 195. In FIG. 4, R denotes a red pixel, G denotes a green pixel, and B denotes a blue pixel. An edge 191 of the opening 195 in FIG. 4A is in an area of the first electrode 171. The first electrode 171 of FIG. 4A has an octagonal plane, but the planar shape of the first electrode 171 may be different in another embodiment.

FIG. 4B illustrates a plan view of an embodiment of a recessed portion 221 below the first electrode 171 of FIG. 4A. The recessed portions 221 may have a circular plane shape or another shape. For example, the recessed portion 221 may have a planar polygonal shape, an elliptical shape, a linear shape, or another shape. The recessed portions 221 are inside the edge 191 of the opening 195. The recessed portions 221 may be defined symmetrically with respect to a central portion of the opening 195 or may be arranged asymmetrically.

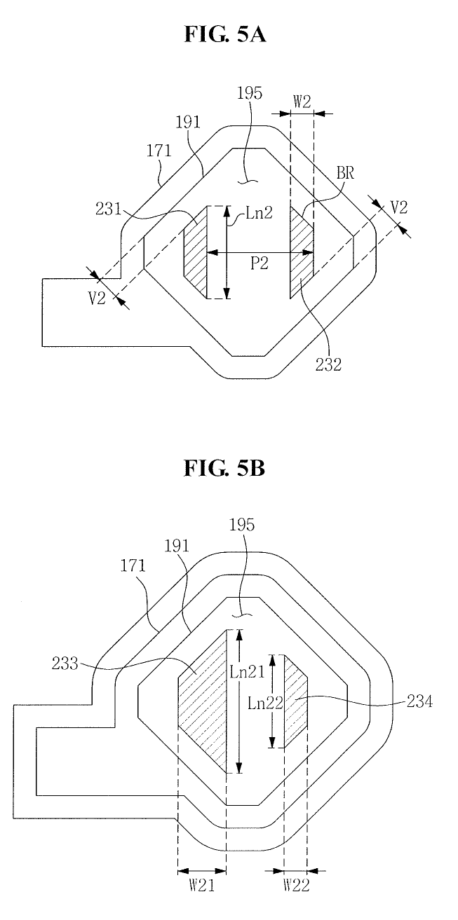

FIGS. 5A and 5B illustrate plan views of another embodiment of a first electrode 171, an opening 195, and recessed portions 231, 232, 233, and 234. Referring to FIG. 5A, two line-shaped recessed portions 231 and 232 are below one first electrode 171. For example, a protective layer 130 has two recessed portions 231 and 232 in one opening 195. The two recessed portions 231 and 232 have a line shape extending in the vertical direction with respect to the drawing. The two recessed portions 231 and 232 extend in a substantially same direction and may have a symmetrical shape or an identical shape.

Each of the recessed portions 231 and 232 is spaced apart from the edge 191 of the opening 195 by a predetermined distance V2. In addition, each of the recessed portions 231 and 232 has a width W2 and a length Ln2 and the two recessed portions 231 and 232 are arranged at a predetermined pitch P2.

Referring to FIG. 5B, a plurality of asymmetric recessed portions 233 and 234 are below one first electrode 171. For example, a protective layer 130 has a first recessed portion 233 and a second recessed portion 234 overlapping one opening 195. The planar area of the first recessed portion 233 may be greater than the planar area of the second recessed portion 234. In such an exemplary embodiment, the first recessed portion 233 does not overlap a wiring below the protective layer 130. The second recessed portion 234 may overlap a wiring below the protective layer 130. In order to prevent contact with the wiring below the first electrode 171 at the second recessed portion 234, the area of the second recessed portion 234 may be reduced to a depth less than a depth of the first recessed portion 233 not overlapping the wiring therebelow.

For example, the length Ln21 of the first recessed portion 233 may be greater than the length Ln22 of the second recessed portion 234, and the width W21 of the first recessed portion 233 may also be greater than the width W22 of the second recessed portion 234.

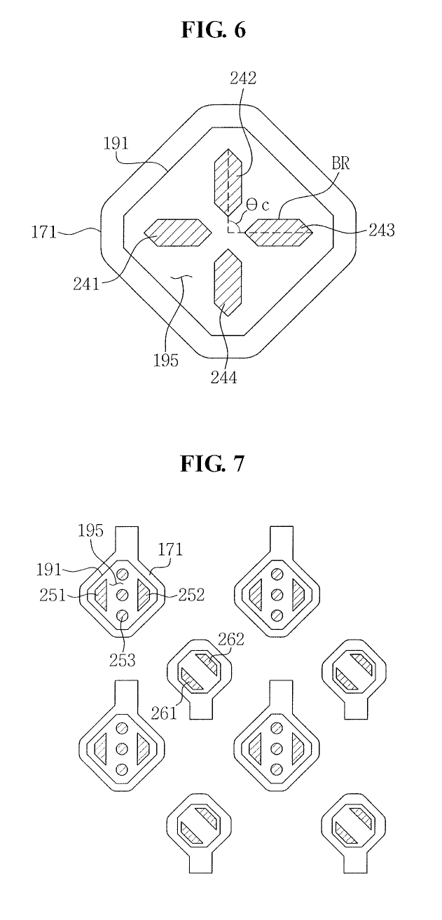

FIG. 6 illustrates a plan view of another embodiment of a first electrode 171, an opening 195 and recessed portions 241, 242, 243 and 244. Referring to FIG. 6, a protective layer 130 includes a plurality of line-shaped recessed portions 241, 242, 243, and 244 overlapping one opening 195 and arranged in a radial direction.

For example, four line-shaped recessed portions 241, 242, 243, and 244 overlapping one opening 195 may be defined in the protective layer 130. In such an exemplary embodiment, an angle θc between extending directions of the recessed portions 241, 242, 243, and 244 is in a predetermined range, e.g., about 60 degrees to about 120 degrees. In one embodiment, the four recessed portions 241, 242, 243, and 244 may be defined so that the angle between the extending directions is about 90 degrees. As such, the recessed portions 241, 242, 243 and 244 may be symmetrically defined with respect to the center of the opening 195. The recessed portions 241, 242, 243 and 244 may be arranged at different angles in another embodiment.

When the recessed portions 231 and 232 extend in one direction as illustrated in FIG. 5A, color shift and WAD in the direction perpendicular to the extending direction of the recessed portions 231 and 232 may be improved. However, the degree of improvement in color shift and WAD in substantially a same direction as the extending direction of the recessed portions 231 and 232 may be insignificant. For example, when the recessed portions 231 and 232 are as illustrated in FIG. 5A, color shift and WAD in the horizontal (e.g., left and right) direction in the drawings may be improved, but the improvement in color shift and WAD in the vertical direction may be minimal or below a desired amount.

On the other hand, when the recessed portions 241, 242, 243, and 244 are defined in a radial direction, for example, as illustrated in FIG. 6, color shift and WAD may be improved in both the horizontal (left and right) direction and the vertical direction.

FIG. 7 illustrates a plan view of another embodiment of a first electrode 171, an opening 195, and recessed portions 251, 252, 253, 261, and 262. Referring to FIG. 7, a protective layer 130 includes recessed portions 251, 252, 261, and 262 in a line shape and a recessed portion 253 in a dot shape. The recessed portions 251, 252, 261, and 262 may have, for example, a linear or quadrangular shape below the first electrode 171 illustrated in FIG. 7. The recessed portion 253 having a dot shape may be therebelow. The recessed portions 251, 252, 253, 261, and 262 may be arranged asymmetrically with respect to the center of the opening 195.

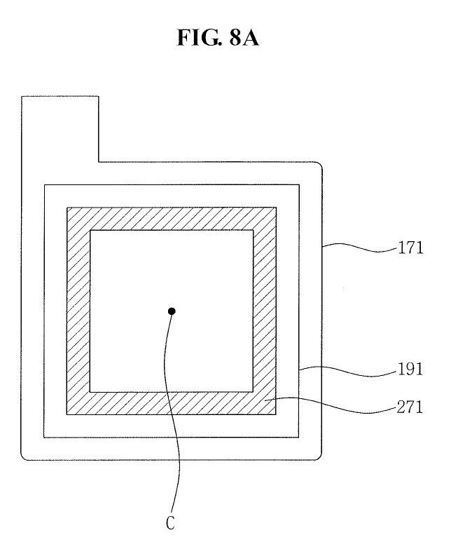

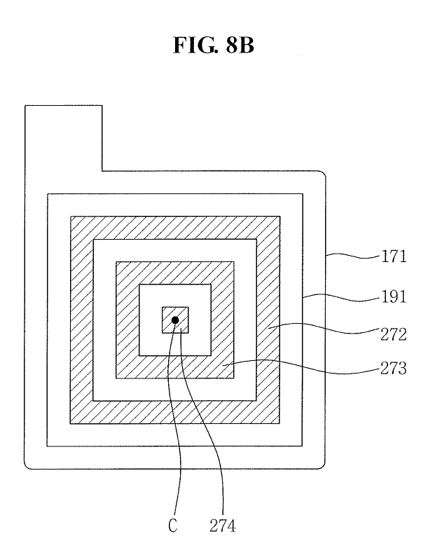

FIGS. 8A and 8B illustrate plan views of another embodiment of a first electrode 171, an opening 195, and recessed portions 271, 272, 273, and 274. Referring to FIG. 8A, a protective layer 130 has a recessed portion 271 in a closed loop shape surrounding a center C of the opening 195.

Referring to FIG. 8B, the protective layer 130 includes a plurality of recessed portions 272 and 273 in a closed loop shape surrounding the center C of the opening 195 and a recessed portion 274 in a dot shape.

When the recessed portions 271, 272, 273 and 274 are in a closed loop shape as illustrated in FIGS. 8A and 8B, color shift and WAD may be improved in all directions.

FIG. 9A illustrates a cross-sectional view of an example of WAD, and FIG. 9B is a graph illustrating an example of wavelength variation according to viewing angle.

The OLED display device 101 has a multilayer stack structure (e.g., see FIG. 3). Light from the organic light emitting layer 172 is emitted in an outward direction, passing through the multilayer structure. According to an exemplary embodiment, the light generated in the organic light emitting layer 172 passes through the second electrode 173 and is emitted outwardly.

When optical resonance occurs in the course of light repeating reflection between two reflective surfaces, energy of the light increases and the light having the increased energy may relatively easily pass through the multilayer stacked structure and emitted outwardly. Such a structure that allows light to resonate between two reflective layers may be referred to as a resonance structure. The distance between the two reflective layers at which resonance occurs may be referred to as a resonance distance. The resonance distance depends on the wavelength of the light.

Since the first electrode 171 is a reflective electrode and the second electrode 173 is a transflective electrode in the OLED display device 101 according to an exemplary embodiment, light may be reflected between the first electrode 171 and the second electrode 173 and light resonance may occur. When the wavelength of light emitted from the organic light emitting layer 172 is denoted as λ1 and the distance between the first electrode 171 and the second electrode 173 is denoted as t1, light resonance may occur when the following Formula 1 is satisfied:

2·n1·t1=m1·λ1 (1)

where n1 denotes an average refractive index between the first electrode 171 and the second electrode 173 and m1 is an integer. The distance t1 between the first electrode 171 and the second electrode 173 may be the distance between an upper surface of the first electrode 171 and a lower surface of the second electrode 173 opposing each other.

In an exemplary embodiment, although the same color is displayed in the organic light emitting layer 172, different colors may be visually recognized depending on the viewing angle of the observer. For example, when a display surface of the display device that emits white light is viewed from the front side, white is recognized. However, when viewed from the lateral side, a bluish or yellowish color may be recognized. This phenomenon is called WAD, which may be caused by a path difference of light depending on the viewing angle.

Referring to FIG. 9A, light L1 viewed from the front side may resonate according to Formula 1. On the other hand, light L2 emitted toward the lateral side is incident to an interface Sb at an angle θi in a medium having a thickness t1 and a refractive index n1 and is emitted at an angle θo.

In an exemplary embodiment, when the wavelength of the light L2 emitted toward the lateral side is denoted as λ, the following Formula 2 may be satisfied in order for light on different paths to resonate.

2·nc·t1·cos(θi)=m·λ (2)

where m is an integer.

In Formula 2, when the incident angle θi at the interface Sb increases, the value of cos(θi) decreases. Accordingly, the resonance condition may change and the resonance wavelength may change. As a result, the wavelength of the light L2 emitted toward the lateral side may differ from the wavelength of the light L1 emitted toward the front side. For example, when the incident angle θi increases, the value of cos(θi) decreases. Accordingly, the wavelength λ that satisfies the resonance condition becomes small. Accordingly, the light L2 having a shorter wavelength than the wavelength of light L1 emitted toward the front side is emitted toward the lateral side.

FIG. 9B illustrates an example of a spectrum of light A1 observed from the front side and a spectrum of a light A2 observed from the lateral side at an angle of about 45 degrees. Referring to FIG. 9B, a peak wavelength of the light A2 observed from the lateral side of about 45 degrees is shifted to the short wavelength, compared with a peak wavelength of the light A1 observed from the front side.

FIG. 10 illustrates a cross-sectional view of an example of resonance at the recessed portion 210. As described above, according to an exemplary embodiment, the first electrode 171 of the OLED display device 101 is a reflective electrode and the second electrode 173 thereof is a transflective electrode. Accordingly, light is reflected between the first electrode 171 and the second electrode 173, and light resonance occurs.

According to an exemplary embodiment, resonance also occurs between the first electrode 171 and the second electrode 173 at the recessed portion 210. At the recessed portion 210, light L31, L32, and L33 resonating in the direction perpendicular to surfaces of the first electrode 171 and the second electrode 173 are generated in a same organic light emitting layer 172 to resonate, but are emitted in different directions.

For example, referring to FIG. 10, light L31, L32, and L33 resonating in directions perpendicular to the surfaces of the first electrode 171 and the second electrode 173 at different points R1, R2, and R3 of the recessed portion 210 are not only emitted in the frontal direction but also in the lateral direction. Accordingly, light L31 and L33 viewed from the lateral side and light L32 viewed from the front side have a substantially same wavelength so that color shift and WAD in the lateral direction may be reduced or substantially prevented.

When light is totally reflected between two reflective layers, the light may not be externally emitted and is extinguished. For example, when light is totally reflected between the first electrode 171 and the second electrode 173, the light is only horizontally guided, but is not emitted outwardly but is extinguished. However, when the recessed portions 210 and 220 are defined, the path of light that is horizontally guided is changed, and the totally reflected light may be emitted outwardly. Accordingly, luminous efficiency of the OLED display device 101 may be improved.

FIG. 11 illustrates a cross-sectional view of an embodiment of an OLED display device 102 which includes a thin film encapsulation layer 140 on a second electrode 173 to protect an OLED 170. The thin film encapsulation layer 140 substantially prevents moisture or oxygen from permeating into the OLED 170.

The thin film encapsulation layer 140 includes at least one inorganic layer 141 and 143 and at least one organic layer 142 that are alternately disposed. The thin film encapsulation layer 140 illustrated in FIG. 11 includes two inorganic layers 141 and 143 and one organic layer 142. The thin film encapsulating layer 140 may have a different structure in another embodiment.

The inorganic layers 141 and 143 may include at least one of metal oxide, metal oxynitride, silicon oxide, silicon nitride, and silicon oxynitride. The inorganic layers 141 and 143 are formed by a chemical vapor deposition (CVD) method, an atomic layer deposition (ALD) method, or another method.

The organic layer 142 may include, for example, a polymer material. The organic layer 142 may be formed, for example, through a thermal deposition process. The thermal deposition process for forming the organic layer 142 proceeds within a temperature range that does not damage the OLED 170. The organic layer 142 may be formed by a different method in another embodiment.

The inorganic layers 141 and 143 have a high density of thin film and therefore may suppress permeation of moisture or oxygen. e.g., moisture and oxygen are blocked by the inorganic layers 141 and 143 from penetrating into the OLED 170.

Any moisture or oxygen that passes through the inorganic layers 141 and 143 are blocked again by the organic layer 142. The organic layer 142 may also function as a buffer layer to reduce the stress between the inorganic layers 141 and 143 and the organic layer 142. The organic layer 142 may have planarizing characteristics. In this case, the uppermost surface of the thin film encapsulation layer 140 may be planarized by the organic layer 142.

The thin film encapsulation layer 140 may have a predetermined thin thickness. Accordingly, the organic light emitting display 102 may be produced to have a significantly thin thickness. Such an OLED display device 102 may have excellent flexible characteristics.

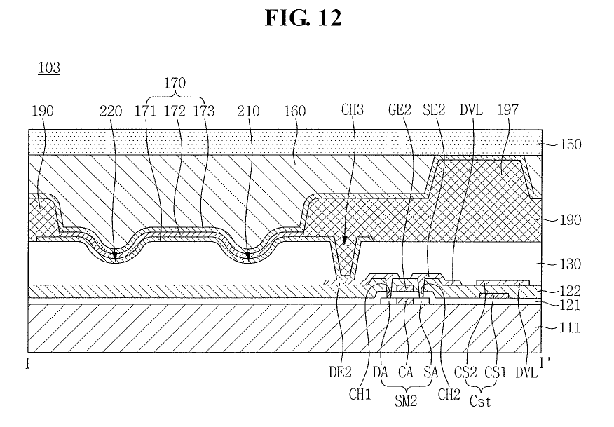

FIG. 12 illustrates a cross-sectional view of another embodiment of an OLED display device 103 which includes a sealing member 150 on a second electrode 173 to protect an OLED 170. The sealing member 150 may include a light transmissive insulating material such as glass, quartz, ceramic and plastic. The sealing member 150 has a plate shape and is attached to a substrate 111 to protect the OLED 170.

A filler 160 may be between the OLED 170 and the sealing member 150. The filler 160 may include, for example, an organic material, e.g., a polymer. In addition, a protective layer including a metal or an inorganic material may be on the OLED 170 to protect the OLED 170.

The OLED display device 103 may also include a spacer 197 on a pixel defining layer 190. The spacer 197 serves to maintain a space between the substrate 111 and the sealing member 150. The spacer 197 protrudes toward an upper portion of the pixel defining layer 190, that is, opposite to the protective layer 130.

Similar to the pixel defining layer 190, the spacer 197 may include a polyacrylic resin or a polyimide (PI) resin. In one embodiment, the spacer 197 may be integrally formed with the pixel defining layer 190, for example, by a photolithography process using a photosensitive material. In other embodiments, the pixel defining layer 190 and the spacer 197 may be sequentially or separately formed or may include different materials. The spacer 197 has a predetermined shape, e.g., a truncated pyramid, a prism, a truncated cone, a cylinder, a hemisphere, or a hemi-spheroid.

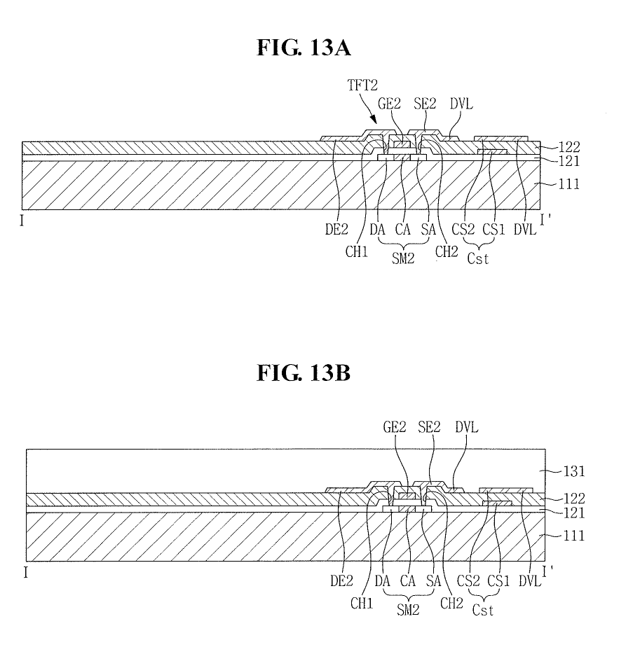

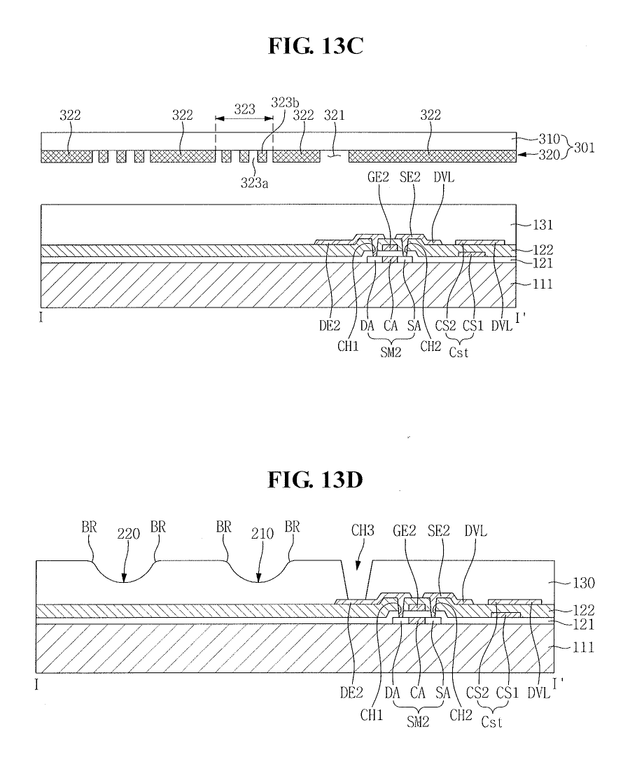

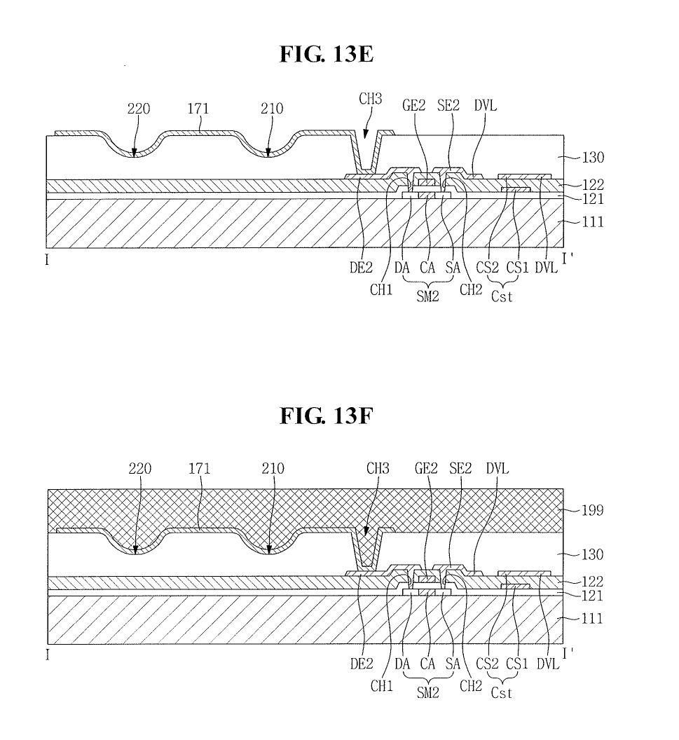

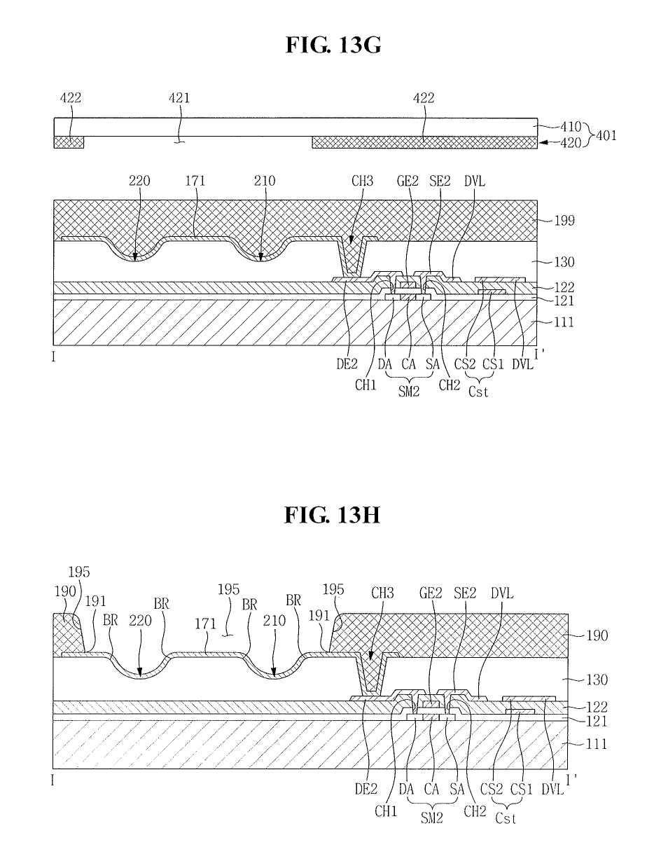

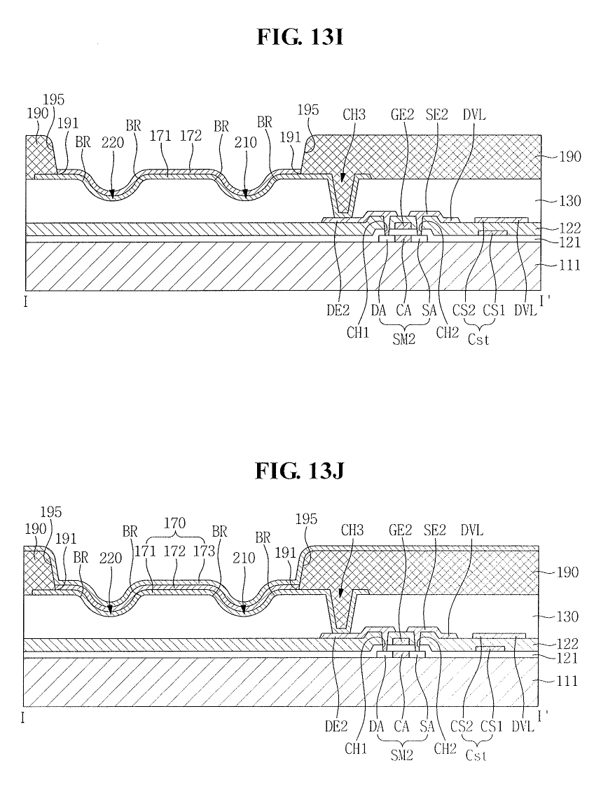

FIGS. 13A-13J illustrate stages of an embodiment of a method for manufacturing an OLED display device, which, for example, may be the OLED display device 101.

Referring to FIG. 13A, the method includes forming a driving thin film transistor TFT2 and a capacitor Cst on a substrate 111. A switching thin film transistor TFT1, a gate line GL, a data line DL, a driving voltage line DVL, and/or other wirings, circuit elements, for features may also be formed on the substrate 111.

Referring to FIG. 13B, a photosensitive material is applied over an entire surface of the substrate 111 including the driving thin film transistor TFT2, to thereby form a photosensitive material layer 131. The photosensitive material may be, for example, a photodegradable polymer resin.

Referring to FIG. 13, a first pattern mask 301 is above and spaced apart from the photosensitive material layer 131. The first pattern mask 301 includes a light blocking pattern 320 on a mask substrate 310. The light blocking pattern 320 includes at least three areas, each having different light transmittances. Such a first pattern mask 301 may also be referred to as a half tone mask.

The mask substrate 310 may be transparent glass, plastic substrate, or a substrate made of another material having light transmittance and mechanical strength.

The light blocking pattern 320 may be formed by selectively applying a light blocking material to the mask substrate 310. The blocking pattern 320 includes a transmissive portion 321, a light blocking portion 322 and a semi-light transmissive portion 323. The transmissive portion 321 is an area through which light is transmitted, and is above an area to be defined with a third contact hole CH3. The light blocking portion 322 is a portion at which light transmission is blocked and may be formed by applying a light blocking material to the mask substrate 310.

The semitransmissive portion 323 is a portion through which a part of an incident light is transmitted and is above an area to be defined with recessed portions 210 and 220. For example, the semi-light transmissive portion 323 may have a structure in which a light transmissive area 323a and a light blocking slit 323b are alternately disposed. In such an exemplary embodiment, light transmittance of the semi-light transmissive portion 323 may be adjusted by adjusting an interval between the light transmissive area 323a and the light blocking slit 323b.

When the recessed portions 210 and 220 having a small area are defined, the semi-light transmissive portion 323 may only include the light transmitting area 323a. In such an exemplary embodiment, area and depth of the recessed portions 210 and 220 may be adjusted by adjusting an area of the light transmitting area 323a. In one embodiment, light transmittance of the semi-light transmissive portion 323 may be adjusted by adjusting a concentration of the light blocking material.

The photosensitive material layer 131 is patterned through exposure using the first pattern mask 301 illustrated in FIG. 13C, to thereby form a protective layer 130 including the recessed portions 210 and 220. The photosensitive material layer 130 may, for example, be exposed and then developed, such that a pattern such as the recessed portions 210 and 220 and the third contact hole CH3 are defined.

Referring to FIG. 13D, after the exposure and development, the photosensitive material layer 131 is thermally cured to form the protective layer 130. Polymeric resins forming the photosensitive material layer 131 partially flow in the thermal curing process to form gently curved recessed portions 210 and 220.

Referring to FIG. 13E, a first electrode 171 is formed on the protective layer 130 and is electrically connected to the second drain electrode DE2 through the third contact hole CH3. The first electrode 171 is also in the recessed portions 210 and 220.

Referring to FIG. 13F, a photosensitive material layer 199 for forming a pixel defining layer is disposed on the substrate 111 including the first electrode 171 and the protective layer 130. The photosensitive material layer 199 may include, for example, a photodegradable polymer resin. Such a photodegradable polymer resin may include, for example. at least one of a polyimide (PI) based resin, a polyacrylic resin, a PET resin and a PEN resin. According to an exemplary embodiment, the photosensitive material layer 199 includes polyimide (PI).

Referring to FIG. 13G, a second pattern mask 401 is disposed above the photosensitive material layer 199. The second pattern mask 401 includes a light blocking pattern 420 disposed on a mask substrate 410. The mask substrate 410 may be a transparent glass, plastic substrate, or another type of substrate.

The blocking pattern 420 includes a transmissive portion 421 and a blocking portion 422. The transmissive portion 421 is an area through which light passes and is above an area to be defined with an opening 195. The light blocking portion 422 is a portion where the transmission of light is blocked and is above an area other than the area where the opening 195 is to be defined.

The photosensitive material layer 199 is patterned by a photolithography method using the second pattern mask 201 illustrated in FIG. 13G. For example, the photosensitive material layer 199 is exposed and developed such that the opening 195 is defined (e.g., see FIG. 13H).

Referring to FIG. 13H, the patterned photosensitive material layer 199 is thermally cured to form the pixel defining layer 190. Polymeric resins forming the photosensitive material layer 199 may partially flow during the thermal curing process.

The opening 195 and an edge 191 of the opening 195 are defined by the pixel defining layer 190. The first electrode 171 is exposed from the pixel defining layer 190 by the opening 195. The pixel defining layer 190 exposes an upper surface of the first electrode 171 and protrudes along the periphery of each of the first electrodes 171. The pixel defining layer 190 overlaps an end portion of the first electrode 171 and the opening 195 is above the first electrode 171.

When a pattern is formed in a photolithography method and when the bottom surface of a boundary area of the pattern is not flat, it may be difficult to form a uniform pattern. According to an exemplary embodiment, the edge 191 of the opening 195 does not overlap the recessed portions 210 and 220. For example, the edge 191 of the opening 195 and the recessed portions 210 and 220 may be spaced apart from each other. Accordingly, a recessed portion or an uneven portion are not formed at the edge 191 of the opening 195, and thus the edge 191 of the opening 195 is located on a flat plane.

Since the edge 191 of the opening 195 corresponding to a boundary of the opening 195 is defined on a flat plane, pattern defects may be substantially prevented in the process of forming the pixel defining layer 190.

Referring to FIG. 13I, an organic light emitting layer 172 is formed on the first electrode 171 that is exposed by the opening 195 of the pixel defining layer 190. The organic light emitting layer 172 may be formed, for example, by deposition.

Referring to FIG. 13J, a second electrode 173 is formed on the organic light emitting layer 172. The second electrode 173 may also be formed on the pixel defining layer 190. The second electrode 173 may be formed, for example, by deposition.

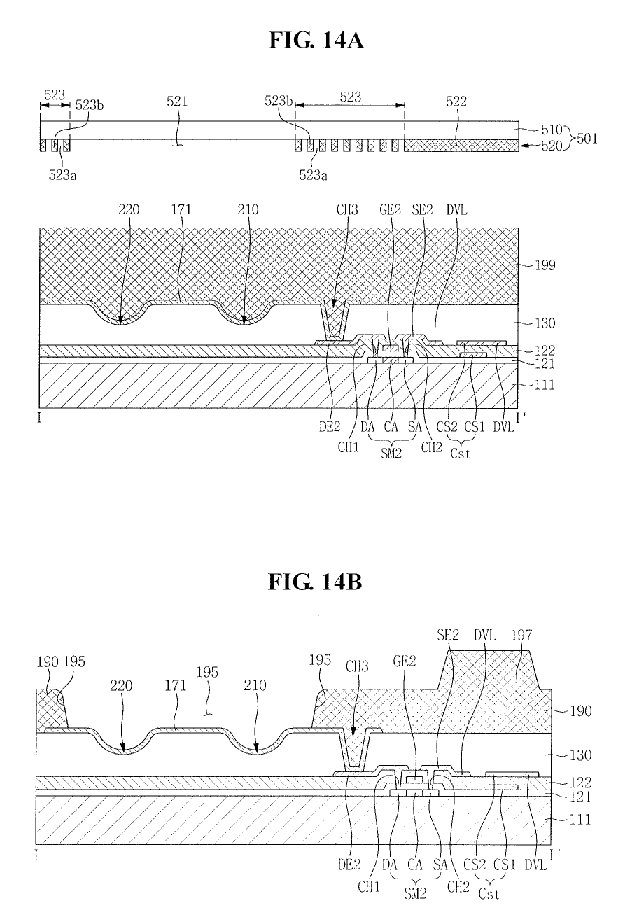

FIGS. 14A and 14B illustrate cross-sectional of another embodiment for manufacturing an OLED display device. FIGS. 14A and 14B illustrate a process of forming a pixel defining layer 190 and a spacer 197. The pixel defining layer 190 and the spacer 197 may be integrally formed through a substantially same process using a substantially same material.

Referring to FIG. 14A, a photosensitive material layer 199 for forming a pixel defining layer is disposed on a substrate 111 including a first electrode 171 and a protective layer 130. A third pattern mask 501 is disposed above the photosensitive material layer 199. The third pattern mask 501 includes a light blocking pattern 520 on a mask substrate 510.

The blocking pattern 520 includes a transmissive portion 521, a light blocking portion 522 and a semi-light transmissive portion 523. The transmissive portion 521 is an area through which light is transmitted and is above an area to be defined with an opening 195. The light blocking portion 322 is a portion at which light transmission is blocked and is above an area where the spacer 197 is to be formed.

The semi-light transmissive portion 523 is a portion through which a part of the incident light is transmitted and is above an area other than an area where the opening 195 and the spacer 197 are to be formed. Referring to FIG. 14A, the semi-light transmissive portion 523 has a structure in which a light transmissive area 523a and a light blocking slit 523b are alternately arranged.

A pattern such as the opening 195 and the spacer 197 are formed after the photosensitive material layer 199 is exposed and developed by an exposure process using the third pattern mask 501.

Referring to FIG. 14B, the patterned photosensitive material layer 199 is thermally cured to form the pixel defining layer 190 and the spacer 197.

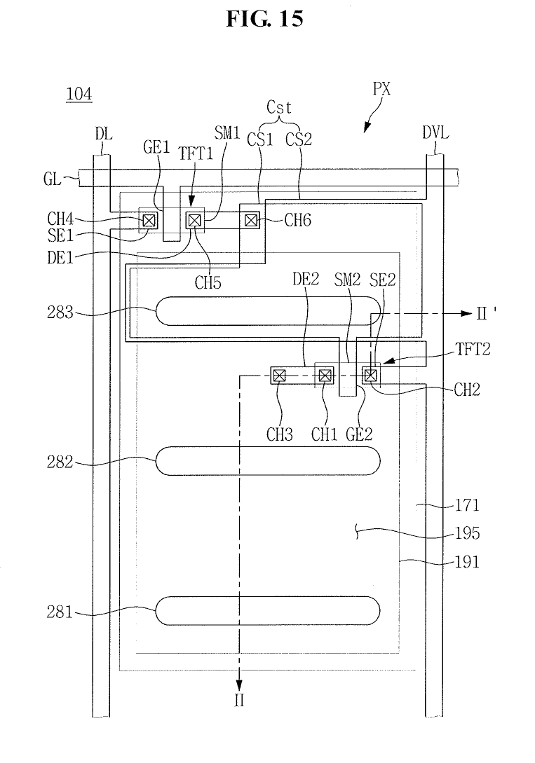

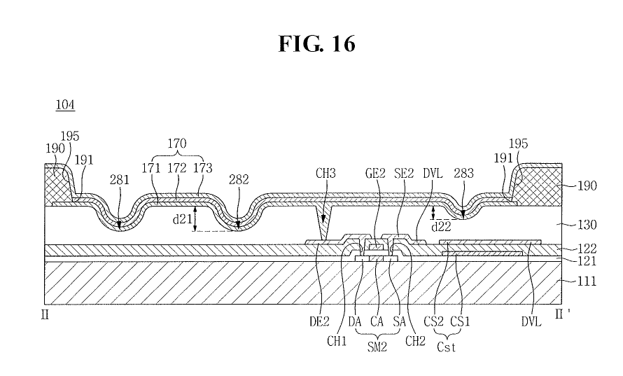

FIG. 15 is a plan view illustrating a pixel PX of an OLED display device 104 according to still another alternative exemplary embodiment, and FIG. 16 is a cross-sectional view taken along line II-II′ of FIG. 15.

Referring to FIGS. 15 and 16, a protective layer 130 includes a plurality of recessed portions. The protective layer 130 includes a first recessed portion 281, a second recessed portion 282, and a third recessed portion 283 in one pixel PX. Of these, the third recessed portion 283 overlaps a capacitor Cst.

The protective layer 130 contacts an insulating interlayer 122 below the first recessed portion 281 and the second recessed portion 282. The protective layer 130 contacts a second capacitor plate CS2 below the third recessed portion 283. Accordingly, the first electrode 171 is not electrically connected to a wiring at the first recessed portion 281 and the second recessed portion 282, even though the first recessed portion 281 and the second recessed portion 282 are deep enough to expose the insulating interlayer 122.

On the other hand, when the third recessed portion 283 is deep and the capacitor Cst is exposed from the protective layer 130, the first electrode 171 may contact the second capacitor plate CS2 at the third recessed portion 283. When the first electrode 171 is connected to wiring other than a second drain electrode DE2 of a driving thin film transistor TFT2. the OLED 170 may be defective.

Accordingly, according to an exemplary embodiment, the recessed portions 281, 282, and 283 have different depths depending on overlap with wiring therebelow. For example, at least one of the two or more recessed portions may have a different depth from a depth of the others.

The third recessed portion 283 overlapping the capacitor Cst (which is one of the wirings therebelow) may have, for example, less depth than depths of the first and second recessed portions 281 and 282 which do not overlap the wirings therebelow, e.g., d22<d21. The depth d22 of the third recessed portion 283 (which overlaps a wiring contacting the protective layer 130) may be, for example, less than the depth d21 of the first and second recessed portions 281 and 282 which do not overlap wiring contacting the protective layer 130.

When the recessed portions 281, 282, and 283 having a narrow area, the depth of the recessed portions 281, 282 and 283 is associated with the width or area of the recessed portions 281, 282, and 283. The depth of the recessed portion which has a narrow area may be adjusted by adjusting an exposure area of a pattern mask used for forming the recessed portion. For example, a deep recessed portion may be defined when the exposure area of the pattern mask is relatively large. According to another exemplary embodiment, one recessed portion 283 of the recessed portions may have a different width from recessed portion 281 or 282.

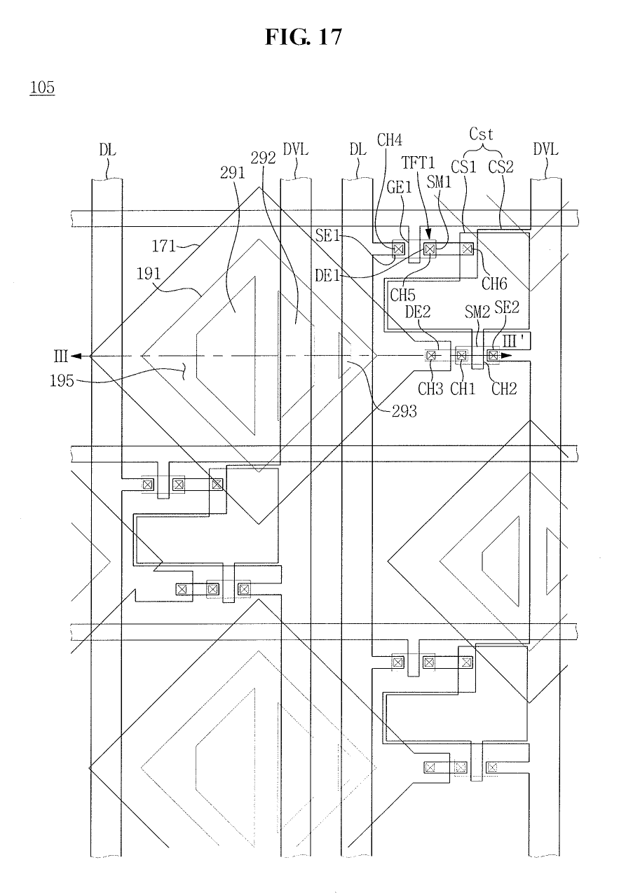

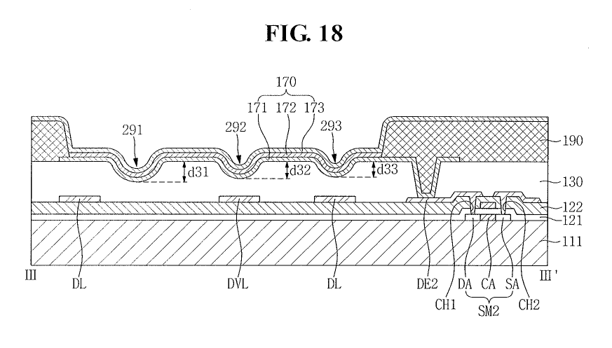

FIG. 17 illustrates an embodiment of a pixel of an OLED display device 105, and FIG. 18 illustrates a cross-sectional view taken along line III-III′ in FIG. 17.

Referring to FIGS. 17 and 18, a protective layer 130 includes a plurality of recessed portions 291, 292, and 293. Referring to FIG. 17, the recessed portions 291, 292, and 293 are arranged asymmetrically below a first electrode 171.

In one embodiment, the protective layer 130 includes a first recessed portion 291, a second recessed portion 292, and a third recessed portion 293 in one pixel PX. A planar area of the first recessed portion 291 is larger than a planar area of the second recessed portion 292 and a planar area of the third recessed portion 293. The first recessed portion 291 does not overlap wiring on an insulating interlayer 122. The second recessed portion 292 overlaps a driving voltage line DVL. The third recessed portion 293 overlaps a data line DL.

The second recessed portion 292 has a relatively small depth in order to prevent the first electrode 171 from contacting the driving voltage line DVL at the second recessed portion 292. For example, a depth d32 of the second recessed portion 292 overlapping the driving voltage line DVL may be less than a depth d31 of the first recessed portion 291 that does not overlap the driving voltage line DVL, e.g., d31>d32.

A depth d33 of the third recessed portion 293 may be less than the depth 31 of the first recessed portion 291 that does not overlap the data line DL, in order to prevent the first electrode 171 from contacting the data line DL at the third recessed portion 293, e.g., d31>d33.

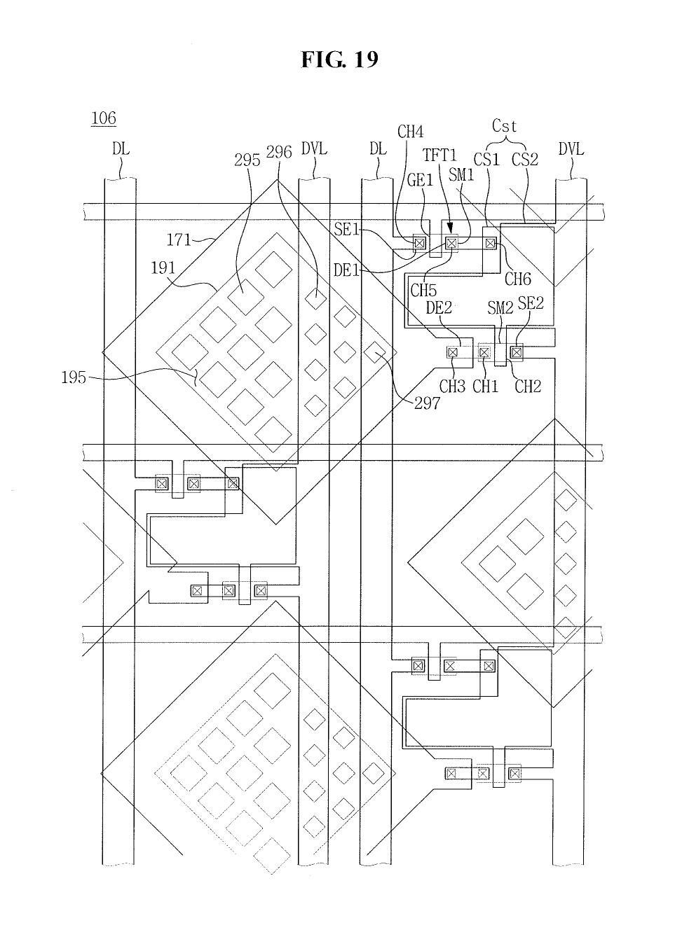

FIG. 19 illustrates a plan view of another embodiment of a pixel of an OLED display device 106. Referring to FIG. 19, a plurality of recessed portions 295, 296, and 297 are below one first electrode 171. The size of at least one of the recessed portions 295, 296, and 297 is different from the side of another recessed portion. For example, a first recessed portion 295 which does not overlap the driving voltage line DVL or the data line DL has a larger planar area than planar areas of the second recessed portion 296 and the third recessed portion 297 which overlap the driving voltage line DVL or the data line DL.

The first recessed portion 295 having a large planar area may have a greater depth than depths of the second recessed portion 296 and the third recessed portion 297 having a small planar area.

The recessed portions 295, 296, and 297 may be defined by exposure using a pattern mask. The depths of the recessed portions 295, 296, and 297 having a relatively narrow area may be adjusted, for example, by adjusting the size of an exposure area of the pattern mask used for forming the recessed portion.

In accordance with one or more of the aforementioned embodiments, an OLED display device has a recessed portion defined in a protective layer. The recessed portion allows light generated in the OLED to be emitted in various directions, so that color shift according to viewing angle may be reduced or prevented. In addition, the recessed portion in the protective layer may be spaced apart from an edge of an opening defined by a pixel defining layer. Accordingly, the edge of the opening is located on a flat plane, and the formation of pattern defects may be reduced or prevented during a process for forming the pixel defining layer.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

What is claimed is:

1. An organic light emitting diode display device, comprising:
a substrate;
a protective layer on the substrate;
a first electrode on the protective layer;
a pixel defining layer on the protective layer and defining an opening that exposes at least a portion of the first electrode;
an organic light emitting layer on the first electrode; and
a second electrode on the light emitting layer, wherein the protective layer has a recessed portion overlapping the opening and wherein the recessed portion is spaced apart from an edge of the opening on a plane.

2. The display device as claimed in claim 1, wherein a height of the protective layer is equal to height of a surface of the substrate at a boundary where the protective layer overlaps the pixel defining layer.

3. The display device as claimed in claim 1, wherein a difference between a height of the protective layer and a height of a surface of the substrate at a boundary where the protective layer overlaps the pixel defining layer is about 0.1 μm or less.

4. The display device as claimed in claim 1, wherein a height of the edge of the opening is equal to a height of a surface of the substrate.

5. The display device as claimed in claim 1, wherein a difference between a height of the edge of the opening and a height of a surface of the substrate is about 0.1 μm or less.

6. The display device as claimed in claim 1, wherein the recessed portion is spaced apart from the edge of the opening by about 0.5 μm to about 5.0 μm.

7. The display device as claimed in claim 1, wherein the recessed portion is spaced apart from the edge of an opening by about 0.5 μm to about 2.0 μm on a plane.

8. The display device as claimed in claim 1, wherein at least a portion of an edge of the recessed portion is parallel to the edge of the opening.

9. The display device as claimed in claim 1, wherein the recessed portion has a width ranging from about 1.0 μm to about 2.0 μm.

10. The display device as claimed in claim 1, wherein the recessed portion has a depth ranging from about 0.2 μm to about 1.0 μm.

11. The display device as claimed in claim 10, wherein the recessed portion has a depth ranging from about 0.3 μm to about 0.7 μm.

12. The display device as claimed in claim 1, further comprising:
a thin film transistor between the substrate and the protective layer,
wherein the first electrode contacts the thin film transistor through a contact hole in the protective layer and wherein a depth of the recessed portion is less than a depth of the contact hole.

13. The display device as claimed in claim 1, wherein the protective layer includes a plurality of recessed portions arranged at a pitch ranging from about 1 μm to about 6 μm.

14. The display device as claimed in claim 13, wherein each of the recessed portions has a linear planar shape.

15. The display device as claimed in claim 14, wherein the recessed portions are parallel to each other.

16. The display device as claimed in claim 13, wherein the recessed portions are in a radial direction.

17. The display device as claimed in claim 13, wherein each of the recessed portions has a dot planar shape.

18. The display device as claimed in claim 13, wherein the recessed portions have different depths.

19. The display device as claimed in claim 1, further comprising:
a spacer on the pixel defining layer.

20. A method for manufacturing an organic light emitting diode display device, the method comprising:
applying a photosensitive material on a substrate to form a photosensitive material layer;
patterning the photosensitive material layer to form a protective layer having a recessed portion;
forming a first electrode on the protective layer and covering the recessed portion;
forming a pixel defining layer on the protective layer, the pixel defining layer defining an opening that exposes at least a portion of the first electrode;
forming a light emitting layer at the opening of the first electrode; and
forming a second electrode on the light emitting layer, wherein the recessed portion overlaps the opening and is spaced apart from an edge of the opening on a plane.

21. The method as claimed in claim 20, wherein a height of the protective layer is equal to a height of a surface of the substrate at a boundary where the protective layer overlaps the pixel defining layer.

22. The method as claimed in claim 20, wherein a difference between a height of the protective layer and a height of a surface of the substrate at a boundary where the protective layer overlaps the pixel defining layer is about 0.1 μm or less.

23. The method as claimed in claim 20, wherein forming the protective layer includes patterning the photosensitive material layer and then thermally curing the patterned photosensitive material layer.
